(19) United States
(12) Patent Application Publication
(10) Pub. No.: US 2007/0126016 A1
(43) Pub. Date: Jun. 7, 2007

(54) LIGHT EMITTING DEVICE AND MANUFACTURE METHOD THEREOF

(75) Inventors: Tzer-Perng CHEN, Hsinchu (TW); Jen-Chau WU, Hsinchu (TW)

Correspondence Address: INGRASSIA FISHER & LORENZ, P.C., 7150 E. CAMELBACK, STE. 325, SCOTTSDALE, AZ, 85251, US

(73) Assignee: EPISTAR CORPORATION, Hsinchu (TW)

(21) Appl. No.: 11/674,371

(22) Filed: Feb. 13, 2007

Related U.S. Application Data
(63) Continuation-in-part of application No. 11/249,680, filed on Oct. 12, 2005, now Pat. No. 7,192,797.

(51) Int. Cl. H01L 33/00

(52) U.S. Cl. 257/96

(57) ABSTRACT

A flip-chip LED including a light emitting structure, a first dielectric layer, a first metal layer, a second metal layer, and a second dielectric layer is provided. The light emitting structure includes a first conductive layer, an active layer, and a second conductive layer. The active layer is disposed on the first conductive layer, and the second conductive layer is disposed on the active layer. The first metal layer is disposed on the light emitting structure and is contact with the first conductive layer, and part of the first metal layer is disposed on the first dielectric layer. The second metal layer is disposed on the light emitting structure and is in contact with the second conductive layer, and part of the second metal layer is disposed on the first dielectric layer. The second dielectric layer is disposed on the first dielectric layer. The first conductive layer includes a rough surface so as to improve a light extraction efficiency.

### CROSS REFERENCE TO RELATED APPLICATIONS

This application claims the right of priority based on U.S. patent application Ser. No. 11/249,680 entitled “Light Emitting Device And Manufacture Method Thereof”, filed on Oct. 12, 2005, which claims the right of priority based on Taiwan Patent Application No. 094103370 entitled “Light Emitting Device and Manufacture Method thereof”, filed on Feb. 03, 2005, and is incorporated herein by reference and assigned to the assignee herein.

### FIELD OF INVENTION

The present invention relates to a light emitting device and a method for manufacturing the same. In addition, the present invention relates to a light emitting device array and a method for manufacturing the same.

### BACKGROUND OF THE INVENTION

For conventional light emitting device (LED) packages, a LED chip is mounted onto the sub-mount using the epoxy put thereon to form a LED element, and the process is called “Die Bonding”. Typically, the epoxy used in “Die Bonding” can be silver filled epoxy or other non-conductive resin. Then, the LED elements are assembled onto the circuit board. For a flip-chip LED, the p-type conductive layer and the n-type conductive layer are exposed on the same side to have the positive electrode and the negative electrode on the same side of the LED structure. And the LED structure with the positive electrode and the negative electrode is flipped and disposed on the solder without wire bonding. However, conventional flip-chip LEDs still require “Dicing” and “Die Bonding” for connecting and mounting the circuit board. If the electrodes of flip-chip LEDs have large contact area to be directly connected to the circuit board, a number of conventional packaging processes for LEDs can be skipped.

The operating current of a conventional LED is typically several tens to several hundreds of mAs. Therefore, the brightness of a conventional LED is not suitable for illumination purpose. When lots of LEDs are assembled into a LED lamp to improve the brightness, the volume of the LED lamp increases accordingly, which results in the loss of its market competitiveness. Therefore, to improve the brightness of a single LED is a necessary approach. However, as the LED advances towards high brightness, the operating current and power of a single LED become several times to several hundred times than those that a conventional LED requires. For example, the operating current of a high brightness LED is about several hundreds of mAs to several Amps (A). As a result, the heat generated by the LED becomes an important issue. “Heat” seriously affects the performance of LEDs; for example, the thermal effect influences the wavelength of lights emitted from the LED, reduces the brightness of lights generated from the semiconductor device, and damages the LED device. Therefore, how to dissipate heat generated by the high power LED become the important issue of the LEDs.

US Applications Nos. 2004/0188696 and 2004/0203189 disclosed a LED package and the method for manufacturing the same based on the Surface Mount Technology (SMT). Each LED package includes a LED chip, and each chip is flip-chip bonded onto a frontside of the sub-mount wafer using boning bump. A plurality of arrays of openings are drilled into the electrically insulating sub-mount wafer. A metal is applied to the drilled openings to produce a plurality of via arrays. The p-type and n-type contacts of each flip-chip bonded LED electrically communicate with a solderable backside of the sub-mount wafer through a via array. A thermal conduction path is provided for thermally conducting heat from the flip-chip bonded LED chip to the solderable backside of the sub-mount wafer. Subsequent to the flip-chip bonding, the sub-mount wafer is separated to produce the surface mount LED packages.

However in US Applications Nos. 2004/0188696 and 2004/0203189, it requires drilled via array with filled metal within the sub-mount wafer and thus increases the manufacturing cost. Furthermore, it becomes complicated to flip-chip bond each chip onto the sub-mount wafer using bonding bump. Therefore, it would be beneficial if the LED packages have excellent thermal conductive paths without the provision of the sub-mount wafers.

### SUMMARY OF THE INVENTION

One aspect of the present invention is to provide a structure of a light emitting device which facilitates the light emitting efficiency of the LED.

Another aspect of the present invention is to provide a LED in which the electrodes are effective thermal conductive paths.

A further aspect of the present invention is to provide a LED in which the electrodes connect directly to the circuits of the circuit board.

A further another aspect of the present invention is to provide a LED with a rough surface to improve the light extraction efficiency.

A still further aspect of the present invention is to provide a LED array and a method for manufacturing the same. The LED array includes a plurality of LEDs on a substrate, and the electrodes of each LED connect directly to the circuits of the circuit board. After the plurality of LEDs are disposed on the circuit board, the substrate is removed and the surface of each LED can be further processed so as to improve the light extraction efficiency.

In one embodiment, the present invention provides a method of forming a light emitting device (LED). The method includes: (a) forming a light emitting structure, the light emitting structure including a substrate, a first conductive layer on the substrate, an active layer on the first conductive layer, and a second conductive layer on the active layer, the active layer being a light emitting layer; (b) forming a first dielectric layer on the light emitting structure; (c) forming a second dielectric layer on the first dielectric layer; (d) forming a first metal layer, the first metal layer being disposed on the light emitting structure and electrically-connected to the first conductive layer, a portion of the first metal layer being disposed on the first dielectric layer; (e) forming a second metal layer, the second metal layer being disposed on the light emitting structure and electrically-connected to the second conductive layer, a portion of the second metal layer being disposed on the first dielectric layer; (f) removing the substrate to expose a surface of the first conductive layer; and (g) roughening the surface of the first conductive layer to improve a light extraction efficiency. The first dielectric layer and the second dielectric layer electrically-isolate the first metal layer from the second metal layer. A portion of the first dielectric layer is a transparent layer, and a surface of the first dielectric layer contacting the first metal layer and/or the second metal layer is provided for reflecting the light emitted from the light emitting structure.

In another embodiment, the present invention provides a light emitting device. The LED includes a light emitting structure, a first dielectric layer, a first metal layer, a second metal layer, and a second dielectric layer. The light emitting structure includes a first conductive layer, an active layer, and a second conductive layer. The active layer is disposed on the first conductive layer and is a light emitting layer. The second conductive layer is disposed on the active layer. The first dielectric layer is disposed on the light emitting structure. The first metal layer is disposed on the light emitting structure and is electrically-connected to the first conductive layer. A portion of the first metal layer is disposed on the first dielectric layer. The second metal layer is disposed on the light emitting structure and is electrically-connected to the second conductive layer. A portion of the second metal layer is disposed on the first dielectric layer. The second dielectric layer is disposed on the first dielectric layer. The first dielectric layer and the second dielectric layer electrically-isolate the first metal layer from the second metal layer. A portion of the first dielectric layer is a transparent layer, and a surface of the first dielectric layer contacting the first metal layer and/or the second metal layer is provided for reflecting the light emitted from the light emitting structure. The first conductive layer includes a rough surface so as to improve a light extraction efficiency.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIGS. 1A-1E illustrate cross-sectional views of forming a light emitting device (LED) in accordance with one embodiment of the present invention;

FIG. 1F illustrates LEDs in accordance with an embodiment of the present invention;

FIGS. 2A-2D illustrate cross-sectional views of forming a LED array in accordance with one embodiment of the present invention;

FIG. 2E illustrates the LED array connected to the circuit board in accordance with another embodiment of the present invention;

FIG. 2F illustrates a LED array having a first conductive layer with a rough surface in accordance with one embodiment of the present invention; and

FIG. 2G illustrates a LED array package in accordance with an embodiment of the present invention.

### DETAILED DESCRIPTION OF THE INVENTION

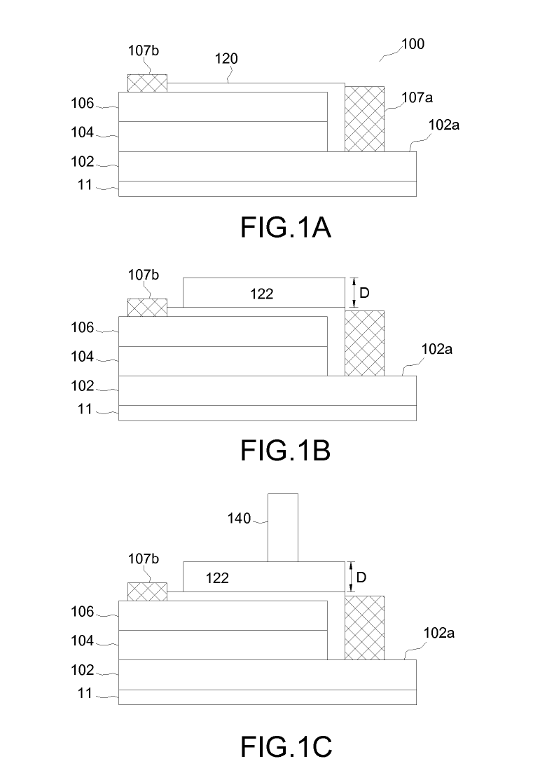

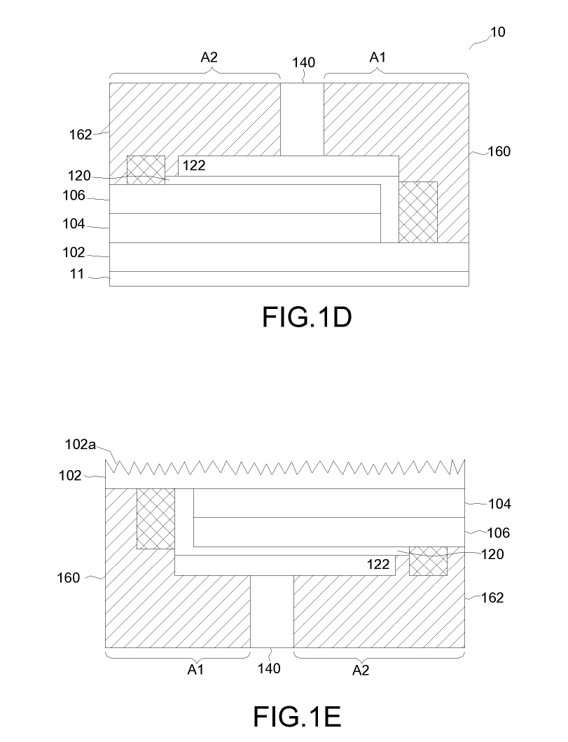

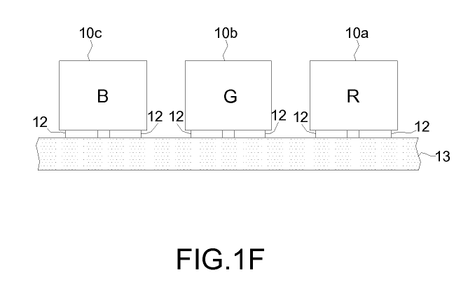

FIGS. 1A-1E illustrate the method for forming a light emitting device (LED) according to one embodiment of the present invention. Referring to FIG. 1A, at first, a light emitting structure 100 is formed. The light emitting structure 100 includes a substrate 11, a first conductive layer 102 as a cladding layer, an active layer 104 disposed on the layer 102 as a light emitting layer, and a second conductive layer 106 disposed on the layer 104 as another cladding layer. Preferably, as shown in FIG. 1A, a bonding pad 107a is disposed on an exposed portion of the layer 102, and another bonding pad 107b is disposed on the layer 106. The manufacture method and the material (e.g., Aluminum) of bonding pads 107a and 107b are well known to those skilled in the art and thus are omitted hereinafter. Furthermore, in one embodiment, the light emitting structure 100 includes a passivation layer 120 to protect the light emitting structure 100. Also, the manufacture method and the material (e.g., SiO₂) of passivation layer 120 are well known to those skilled in the art and thus omitted hereinafter.

The first conductive layer 102 and the second conductive layer 106 can be embodied as any semiconductor materials known to those skilled in the art, preferably as III-V group compound semiconductor, such as AlₓGa_{y}In_{1-x-y}N or AlₓGa_{y}In_{1-x-y}P, wherein 0 ≦x≦1, 0≦y≦1, 0≦x+y≦1, and can be doped with P/N type dopants. Light emitting layer 104 can embodied with conventional materials (e.g., AlₓGa_{y}In_{1-x-y}N or AlₓGa_{y}In_{1-x-y}P) and structures (e.g., Single Quantum Well, Multiple Quantum Well, and Double Heterosture). The principles and mechanisms of the light emitting layer 104 are known to those skilled in the art and thus omitted hereinafter. In addition, the light emitting structure 100 can be manufactured via the process of MOCVD, molecular beam epitaxy (MBE), or hydride vapor phase epitaxy (HVPE).

Next, as shown in FIG. 1B, a first dielectric layer 122 is formed on the light emitting structure 100. Preferably, the layer 122 is a transparent dielectric layer with the thickness D≦20 μm, and the heat generated from the light emitting structure 100 can be easily conducted. The layer 122 can be formed with the material such as SiO₂, Si₃N₄, or the combination of them, and via the processes of E-gun or sputter.

As shown in FIG. 1C, a second dielectric layer 140 is formed on the first dielectric layer 122. The layer 140 can be formed with the material such as SiO₂, silicon-nitride, polymider, bisbenzocyclobutene, or photoresist. Preferably, the thickness of the layer 140 is about 25 μm, and the layer 140 is formed by using a printing technology.

As shown in FIG. 1D, the metal layer 160 is formed after the layer 140 is formed. The metal layer 160 is disposed on the light emitting structure 100 and is electrically connected to the first conductive layer 102. A portion of the metal layer 160 is disposed on the first dielectric layer 122. Also the metal layer 162 is formed on the on the light emitting structure 100 and is electrically connected to the second conductive layer 106. A portion of the metal layer 162 is disposed on the first dielectric layer 122. Meanwhile, the first dielectric layer 122 and the second dielectric layer 140 electrically isolate the metal layer 160 from the metal layer 162. The metal layer 160 or the metal layer 162 can be embodied with materials of Au, Al, Ag, or Alloy of them. Preferably, the metal layer 160 and the metal layer 162 are formed together by using a printing technology or electroplated. After that, the manufacture process for LED 10 is completed.

In one embodiment, the dielectric layer 122 is a transparent dielectric layer. A surface of the dielectric layer 122 contacting the metal layer 160 and/or the metal layer 162 is provided for reflecting the light emitted from the light emitting structure 100. Furthermore, the metal layer 160 and/or the metal layer 162 are thermal conductive paths for the light emitting structure 100. Large contact areas A1 and A2 of the metal layer 160 and the metal layer 162 are also beneficial to the heat dissipation.

Referring to FIG. 1E, after the formation of the structure shown in FIG. 1D, the method further includes a step of removing the substrate 11 to expose the first conductive layer 102. For example, the substrate 11 can be a sapphire substrate or a GaAs substrate. When the substrate 11 is a sapphire substrate, the substrate 11 can be removed by an Excimer laser process. The Excimer laser process can be a KrF Excimer laser with an energy density of 400 mJ/cm², a wavelength of 248 nm, and a pulse width of 38 ns. As the Excimer laser radiates on the sapphire substrate at an elevated temperature, such as 60° C., the sapphire substrate is removed to expose the first conductive layer 102. Alternatively, when the substrate 11 is an GaAs substrate, a solution of NH₄OH:35H₂O₂ or a solution of 5H₃PO4:3H₂O₂:3H₂O can be applied to remove the GaAs substrate to expose the first conductive layer 102.

After the substrate 11 is removed, the method further includes a step of roughening the surface 102a of the first conductive layer 102. For example, the fist conductive layer 102 can be an AlₓGa_{y}In_{1-x-y}N layer, and the surface 102a is roughened by using an etch solution, such as a KOH solution. Alternatively, when the first conductive layer 102 is an AlₓGa_{y}In_{1-x-y}P layer, a solution of HCl and H₃PO₄ can be employed for 15 seconds to roughen the surface 102a of the first conductive layer 102. The rough surface 102a of the first conductive layer 102 is implemented to reduce the possibility of total reflection of light so as to increase a light extraction efficiency of the light emitting device.

Like the LED 10 in FIG. 1E, LED 10a, 10b, and 10c shown in FIG. 1F, are provided with large contact areas, each of which is preferably larger than half of the section area of the LED 10. LED 10a, 10b, and 10c are directly connected to the circuit board 13 by using solder 12 instead of by “Die Bonding” and “Wire Bonding”. In another embodiment, LED 10a is provided for emitting red light, LED 10b for emitting green light, and LED 10c for emitting blue light. Thus LED 10a, 10b, and 10c, when connected to the circuit boards 13, can be used in the image display application.

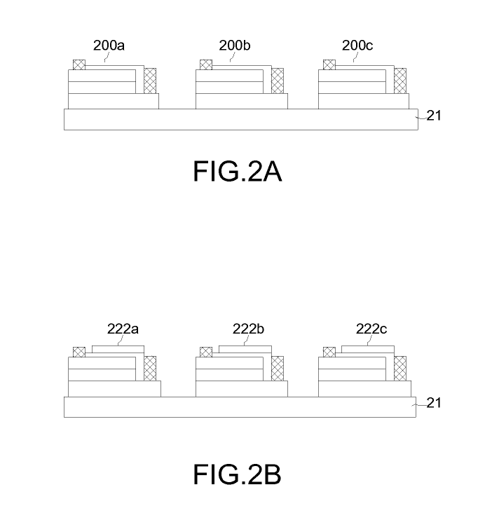

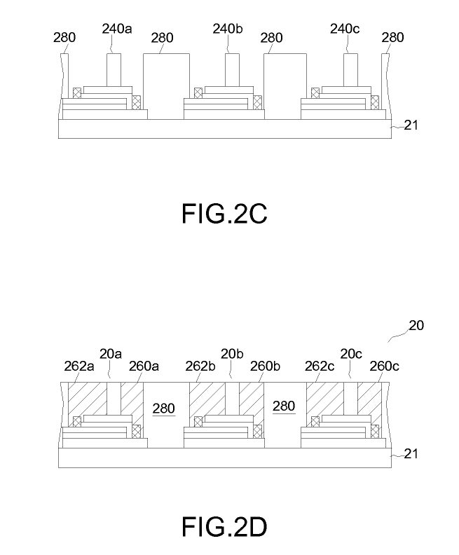

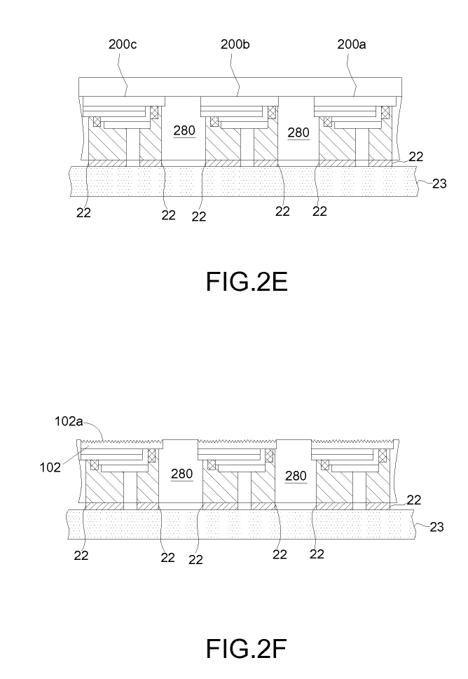

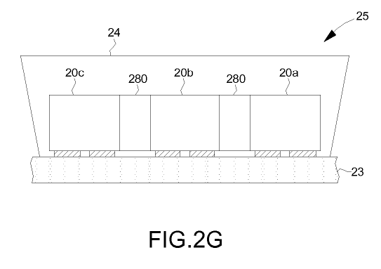

FIGS. 2A-2D illustrate the method for forming a light emitting device (LED) array according to one embodiment of the present invention. Referring to FIG. 2A, at first, a substrate 21 is provided. The substrate 21 can be a sapphire substrate, an GaAs substrate, or other substrates known to those skilled in the art, or the combinations of them. Next, a plurality of light emitting structures 200a, 200b, and 200c are formed on the substrate 21.

The materials and the manufacture processes for light emitting structures 200a, 200b, and 200c can be referred to the elaboration for light emitting structure 100 illustrated by FIGS. 1A-1D. Similarly, light emitting structures 200a, 200b, and 200c can be manufactured via the process of MOCVD, molecular beam epitaxy, or hydride vapor phase epitaxy.

Next, as shown in FIG. 2B, a dielectric layer 222a is formed on the light emitting structure 200a, a dielectric layer 222b is formed on the light emitting structure 200b, and a dielectric layer 222c is formed on the light emitting structure 200c. Preferably, like the layer 122 shown in FIG. 1B, layers 222a, 222b, and 222c are transparent dielectric layers with each thickness D≦20 μm, and the heat generated from the light emitting structures 200a, 200b, and 200c can be easily conducted away. The layers 222a, 222b, and 222c can be formed with the material such as SiO₂, Si₃N₄, or the combination of them, and via the processes of E-gun or sputter.

Later, as shown in FIG. 2C, a dielectric layer 240a is formed on the dielectric layer 222a, a dielectric layer 240b is formed on the dielectric layer 222b, and a dielectric layer 240c is formed on the dielectric layer 222c. The layers 240a, 240b, and 240c can be formed with the material such as SiO₂, silicon-nitride, polymider, bisbenzocyclobutene, or photoresist. Preferably, like the layer 140 in FIG. 1C, the thickness of the layers 240a, 240b, and 240c are about 25 μm respectively, and the layers 240a, 240b, and 240c are formed by using a printing technology. In one embodiment, a dielectric layer 280 is further formed between light emitting structures 200a, 200b, and 200c to electrically isolate LEDs 20a, 20b, and 20c from each other (as shown in FIG. 2D). The dielectric layer 280 can be embodied with the same material (e.g., polyimide) with the layer 240a, 240b, or 240c, and is formed together with them by using a printing technology. Alternatively, the dielectric layer 280 can be embodied with the different material with the layer 240a, 240b, or 240c, and is formed through a different process.

As shown in FIG. 2D, metal layers 260a, 260b, 260c, 262a, 262b, and 262c are formed and can be embodied with materials of Au, Al, Ag, or Alloy of them. Preferably, metal layers 260a, 260b, 260c, 262a, 262b, and 262c are formed together by using a printing technology or electroplated. After that, the manufacture process for LED array 20 including LEDs 20a, 20b, and 20c is completed.

As shown in FIG. 2E, LEDs 20a, 20b, and 20c are provided with large contact areas, and are directly connected to the circuit board 23 by using solders 22. Thereafter, LED array 20 can be separated from the substrate 21 and used in the image display application. For example, after the LEDs 20a, 20b, and 20c are connected to the circuit board 23 by using solder 22, the method further includes a step of removing the substrate 21. For example, the substrate 21 can be a sapphire substrate, and be removed by an Excimer laser process. The Excimer laser process can be a KrF Excimer laser with an energy density of 400 mJ/cm², a wavelength of 248 nm, and a pulse width of 38 ns. As the Excimer laser radiates on the sapphire substrate 21 at an elevated temperature, such as 60° C., the sapphire substrate 21 is removed to expose the first conductive layer 102. Alternatively, when the substrate 11 is an GaAs substrate, a solution of NH₄OH:35H₂O₂ or a solution of 5H₃PO4:3H₂O₂:3H₂O can be applied to remove the GaAs substrate to expose the first conductive layer 102.

After the substrate 21 is removed, the method further includes a step of roughening the surface 102a of the first conductive layer 102. For example, the fist conductive layer 102 can be an AlₓGa_{y}In_{1-x-y}N layer, and the surface 102a is roughened by using an etch solution, such as a KOH solution. Alternatively, when the first conductive layer 102 is an AlₓGa_{y}In_{1-x-y}P layer, a solution of HCl and H₃PO₄ can be employed for 15 seconds to roughen the surface 102a of the first conductive layer 102. The rough surface 102a of the first conductive layer 102 is implemented to reduce the possibility of total reflection of light so as to increase a light extraction efficiency of the light emitting device. In another embodiment, as shown in FIG. 2G, an encapsulating material 24, such as epoxy or any conventional material as appropriate, is applied to enclose the LED array 20 (including LEDs 20a, 20b, and 20c) connected to the circuit board 23 so that a LED device package 25 is formed.

Although specific embodiments have been illustrated and described, it will be obvious to those skilled in the art that various modifications may be made without departing from what is intended to be limited solely by the appended claims.

What is claimed is:

1. A method of forming a light emitting device (LED), comprising:
forming a light emitting structure comprising a substrate, a first conductive layer on said substrate, an active layer on said first conductive layer, and a second conductive layer on said active layer;
forming a first dielectric layer on said light emitting structure;
forming a second dielectric layer on said first dielectric layer;
forming a first metal layer on said light emitting structure and electrically-connected to said first conductive layer, a portion of said first metal layer being disposed on said first dielectric layer;
forming a second metal layer on said light emitting structure so as to be electrically-connected to said second conductive layer and isolated from said first metal by said first and second dielectric layers, a portion of said second metal layer being disposed on said first dielectric layer;
removing said substrate to expose a surface of said first conductive layer; and
roughening said surface of said first conductive layer.

2. The method of claim 1, wherein a portion of said first dielectric layer is a transparent layer, and a surface of said first dielectric layer contacting said first metal layer and/or said second metal layer is provided for reflecting the light emitted from said light emitting structure.

3. The method of claim 1, wherein said first metal layer and/or said second metal layer are formed by using a printing technology or electroplated.

4. The method of claim 1, wherein said second dielectric layer is formed by using a printing technology.

5. The method of claim 1, wherein said substrate includes sapphire or GaAs.

6. The method of claim 1, wherein said substrate is removed by an Excimer laser process or by an etch solution.

7. The method of claim 1, wherein said first conductive layer includes an AlₓGa_{y}In_{1-x-y}N layer or an AlₓGa_{y}In_{1-x-y}P layer.

8. The method of claim 1, wherein said surface of said first conductive layer is roughened by a KOH solution or by a solution of HCl and H₃PO₄.

9. A light emitting device, comprising:
a light emitting structure comprising a first conductive layer, an active layer on said first conductive layer, and a second conductive layer on said active layer;
a first dielectric layer on said light emitting structure;
a second dielectric layer on said first dielectric layer,
a first metal layer disposed on said light emitting structure and electrically-connected to said first conductive layer, a portion of said first metal layer being disposed on said first dielectric layer; and
a second metal layer on said light emitting structure so as to be electrically-connected to said second conductive layer and isolated from said first metal layer by said first and second dielectric layers, a portion of said second metal layer being disposed on said first dielectric layer;
wherein said first conductive layer has a rough surface.

10. The light emitting device of claim 9, wherein a portion of said first dielectric layer is a transparent layer, and a surface of said first dielectric layer contacting said first metal layer and/or said second metal layer is provided for reflecting the light emitted from said light emitting structure.

11. A light emitting device array, comprising:
a carrier;
a plurality of light emitting devices disposed on said carrier, each light emitting device comprising:
a light emitting structure comprising a first conductive layer, an active layer on said first conductive layer, and a second conductive layer on said active layer;
a first dielectric layer on said light emitting structure;
a second dielectric layer on said first dielectric layer;
a first metal layer on said light emitting structure and electrically-connected to said first conductive layer, a portion of said first metal layer being disposed on said first dielectric layer; and
a second metal layer on said light emitting structure so as to be electrically-connected to said second conductive layer and insulated from said first metal layer by said first and second dielectric layers, a portion of said second metal layer being disposed on said first dielectric layer; and
a solder layer provided between said first and said second metal layers of each said light emitting device and said circuit board;
wherein said first conductive layer includes a rough surface.

12. The light emitting device array of claim 11, wherein, for each light emitting device, a portion of said first dielectric layer is a transparent layer, and a surface of said first dielectric layer contacting said first metal layer and/or said second metal layer is provided for reflecting the light emitted from said light emitting structure.

13. The light emitting device array of claim 11, further comprising a third dielectric layer for isolating said plurality of light emitting devices from each other.
